(19) United States
(12) Patent Application Publication
(10) Pub. No.: US 2025/0329663 A1
(43) Pub. Date: Oct. 23, 2025

(54) METHOD FOR MANUFACTURING AN ELECTRONIC CHIP HAVING AN ELECTROMAGNETIC SHIELDING

(71) Applicant: STMicroelectronics International N.V., Geneva (CH)

(72) Inventors: Ludovic FALLOURD, Louans (FR); Sylvain CHARLEY, METTRAY (FR)

(21) Appl. No.: 19/185,705

(22) Filed: Apr. 22, 2025

(30) Foreign Application Priority Data
Apr. 23, 2024 (FR) FR2404174

(51) Int. Cl. H01L 23/552; H01L 21/50; H01L 21/78; H01L 23/00

(52) U.S. Cl. CPC H01L 23/552; H01L 21/50; H01L 24/27; H01L 21/78; H01L 24/13; H01L 24/29; H01L 24/73; H01L 2224/13024; H01L 2224/2784; H01L 2224/2919; H01L 2224/73104

(57) ABSTRACT

A method for manufacturing an electronic chip having an electromagnetic shielding is provided. An example method comprises: i) providing chip comprising: an insulating substrate, covered by an interconnection structure, comprising an insulating layer having conductive tracks formed therein, the conductive tracks emerging onto an upper surface of the interconnection structure and onto one of the sides of the interconnection structure, and connection pads being partially coated with a resin, so as to be connected to the conductive tracks and to be able to be connected to an external element; and ii) forming a conductive coating to cover the substrate and the sides of the interconnection structure, whereby the conductive coating is connected to the conductive tracks.

### CROSS REFERENCE TO RELATED APPLICATION(S)

This application claims the priority benefit of French patent application number 2404174, filed on Apr. 23, 2024, entitled “Procédé de fabrication d'une puce électronique ayant un blindage électromagnétique”, which is hereby incorporated by reference to the maximum extent allowable by law.

### TECHNICAL FIELD

The present disclosure concerns the field of chips of CSP (“Chip-Scale Package”) type or WLCSP (‘Wafer Chip Scale Package’) type. It more particularly concerns a method of manufacturing an electronic chip having an electromagnetic shielding.

### BACKGROUND

Electronic chips comprise a substrate, in which or on which electronic circuits have been manufactured. The substrate is covered with connection areas to allow an assembling of the chip, for example, with a printed circuit board.

However, chips may be submitted to electromagnetic interferences (EMI) which disturb their operation or may even cause significant damage, and/or may generate such electromagnetic interferences.

To protect them from unwanted electromagnetic radiations, it is conventional to form, at component level, a molding around the chip and to form an electromagnetic shielding around the molding. A second molding may optionally be formed on the electromagnetic shielding. The grounding 41 of the electromagnetic shielding may be performed by means of vias and/or of laminates, and can also be used to add an antenna.

To manufacturing electronic chips, it is possible to use low-temperature cofired ceramics (LTCC) comprising a plurality of dielectric layers, conductive materials (for example silk-screened) and holes for interconnecting the different layers. Shielding is then made easily thanks to the use of holes/vias.

However, such chips comprise many interconnection layers and elements and are thus complex to manufacture and/or increase the size of the final chip.

### BRIEF SUMMARY

There exists a need to at least partly improve certain aspects of known methods of manufacturing electronic chips comprising an electromagnetic shielding.

This object is achieved by a method of manufacturing an electronic chip having an electromagnetic shielding comprising the following steps:
i) providing an electronic chip comprising:
   an insulating substrate comprising a lower surface, a lateral surface, and an upper surface,
   an interconnection structure covering the upper surface of the substrate, the interconnection structure comprising an insulating layer having conductive tracks formed therein, pads being arranged on the interconnection structure, the conductive tracks being arranged so as to emerge onto at least one of the sides of the interconnection structure,
   a resin covering an upper surface of the interconnection structure and partially coating the connection pads to be able to connect them to an external element,
ii) forming a conductive coating on the lateral surface and on the lower surface of the substrate as well as on the sides of the interconnection structure, whereby the conductive coating is connected to the conductive tracks on at least one of the sides of the interconnection structure.

According to a specific embodiment, step ii) is carried out by spraying of a solution or by inkjet.

According to a specific embodiment, the solution or the ink contains silver nanoparticles.

According to a specific embodiment, the electronic chip provided at step i) is obtained according to the following steps:
providing a substrate covered by the interconnection structure, connection pads being arranged on the interconnection structure, the conductive tracks being arranged so as to emerge onto at least one of the sides of the interconnection structure,
depositing the resin on the interconnection structures and on the connection pads,
thinning the resin to leave access to part of the connection pads,
possibly, thinning the substrate and/or covering the back side of the chips with an additional resin layer,
cutting the substrate into different chips.

This object is also achieved by an electronic chip comprising:
an insulating substrate comprising a lower surface, a lateral surface, and an upper surface,
an interconnection structure covering the upper surface of the substrate, the interconnection structure comprising an insulating layer having conductive tracks formed therein, connection pads being arranged on the interconnection structure, the conductive tracks being arranged so as to emerge onto at least one of the sides of the interconnection structure,
a resin covering the interconnection structure and leaving access to part of the connection pads,
a conductive coating covering and being in contact with the lateral surface and the lower surface of the substrate of the chip as well as with the sides of the interconnection structure, so as to connect the conductive tracks to the conductive coating on at least one of the sides of the interconnection structure.

According to a specific embodiment, the thickness of the conductive tracks is in the range from 2 to 12 μm.

According to a specific embodiment, the width of the conductive tracks is greater than 10 μm.

According to a specific embodiment, the conductive coating is made of silver.

According to a specific embodiment, the conductive tracks, emerging onto the side of the interconnection structure, comprise a comb-shaped end.

According to a specific embodiment, the conductive tracks emerge onto two opposite sides of the interconnection structure.

This object is also achieved by the use of such an electronic chip in an automotive field, for example in an advanced driver assistance system, in personal electronics, communication equipments, such as a computer, a cell phone (‘smartphone’), a connected object (IoT) or one of their peripherals.

This object is also achieved by an automobile, a communication equipment, such as a computer, a cell phone (‘smartphone’), a connected object (IoT) or one of their peripherals comprising such an electronic chip.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A, FIG. 1B, FIG. 1C, FIG. 1D, FIG. 1E, FIG. 1F, FIG. 1G, FIG. 1H, FIG. 11, and FIG. 1J show cross-section views illustrating different steps of a method of manufacturing an electronic chip having an electromagnetic shielding according to a specific embodiment;

FIG. 2 shows a cross-section view of an electronic chip having an electromagnetic shielding, according to another specific embodiment;

FIG. 3 shows a top view of an electronic chip having an electromagnetic shielding, according to another specific embodiment.

### DETAILED DESCRIPTION

Like features have been designated by like references in the various figures. In particular, the structural and/or functional features that are common among the various embodiments may have the same references and dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

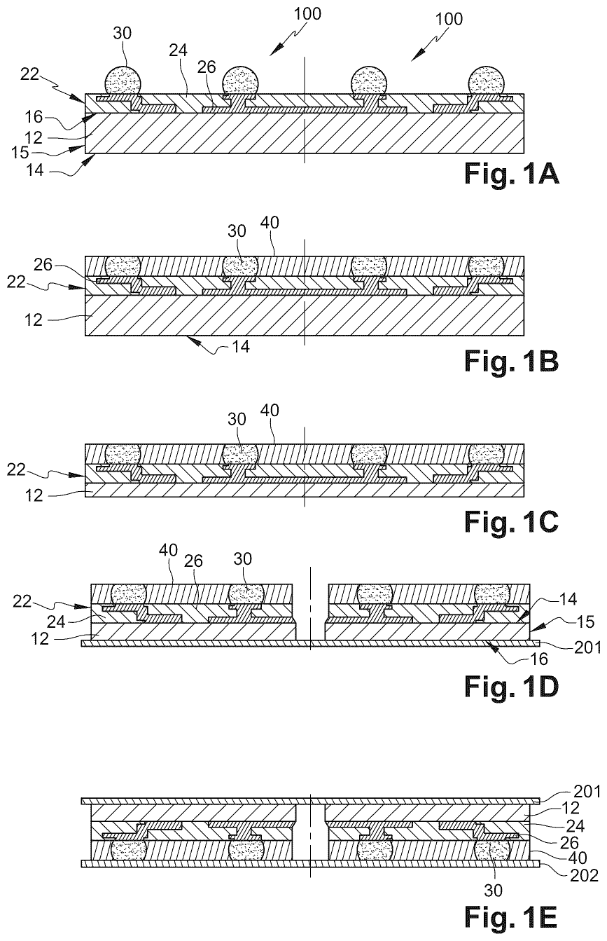

There will now be described in further detail a method of manufacturing an electronic chip having an electromagnetic shielding in relation with FIGS. 1A to 1J.

The method comprises the following steps:
i) providing an electronic chip 100 comprising:
   an insulating substrate 12 comprising a lower surface 14, a lateral surface 15, and an upper surface 16,
   an interconnection structure 22 covering the upper surface 16 of substrate 12, interconnection structure 22 comprising an upper surface, sides, and a lower surface in contact with substrate 12, interconnection structure 22 comprising an insulating layer 24 having conductive tracks 26 formed therein, the conductive tracks emerging on the one hand onto upper surface to form connection areas and on the other hand onto one of the sides of interconnection structure 22,
   connection pads 30 being bonded to connection areas 26,
   a resin 40 covering interconnection structure 22 and leaving access to part of connection pads 30, to be able to connect them to an external element,
ii) forming a conductive coating 50 on the lateral surface 15 and on the lower surface 16 of the substrate 12 of the chip 100 as well as on the sides of interconnection structure 22, whereby conductive tracks 26 are connected to conductive coating 50 on the side of interconnection structure 22.

With such a method, the grounding of electromagnetic coating 50 is directly performed at the tracks 26 of the interconnection structure 22 of chip 100. This enables, not only to gain space since no further additional elements are needed to couple the chip to the coating, but also to leave access to interconnection pads 30 to subsequently assemble the chip to an external element (chips or printed circuits for example).

The electromagnetic (EMI) is connected to ground via the interconnection structure. The conductive tracks connected to the electromagnetic shield are the ground interconnections.

The method does not require covering the sides of substrate 12 with a resin layer, nor forming vias in substrate 12.

More particularly, the method may comprise the following steps:
a) providing a structure comprising a plurality of chips 100, the structure comprising a substrate 12 covered by an interconnection structure 22, connection pads 30 being bonded to interconnection structure 22 (FIG. 1A),
b) depositing a resin 40 on interconnection structures 22 and on connection pads 30 and thinning resin 40 to leave access to part of connection pads 30 (FIG. 1B),
c) preferably, thinning substrate 12 (FIG. 1C) and/or covering the back side 16 of chips 100 with an additional resin layer,
d) separating chips 100, by cutting the structure between chips, whereby individualized chips 100 such as previously defined at step i) are obtained (FIG. 1D), where the cutting step may be carried out by bonding the structure obtained at step c) to a first adhesive 201 (or carrier), substrate 12 being, preferably, bonded to first adhesive 201 on its back side to carry out the cutting step from the front side,
e) simultaneously bonding the cut chips 100 to a second adhesive 202, the chips being bonded on their front side, that is, resin 40 and the connection pads 30 of chips 100 being bonded to second adhesive 202 (FIG. 1E),
f) removing first adhesive 201 (FIG. 1F),
g) if needed, stretching second adhesive 202 to leave more access to the lateral surface of substrate 12 and the sides of the interconnection structures 22 of chips 100 (FIG. 1G),
h) implementing step ii), that is, depositing electromagnetic coating 50 on the back side 14 and on the lateral surface 15 of chip 100 as well as on the sides of interconnection structure 22 (FIG. 1H).

The method may further comprise, after step ii), the following steps:
bonding chips 100 to a third adhesive 203 (carrier), on their back, by bonding coating 50 to third adhesive 203 (FIG. 1I),
removing third adhesive 203 (FIG. 1J).

The steps of the method are, preferably, implemented to simultaneously handle all the chips originating from a same substrate.

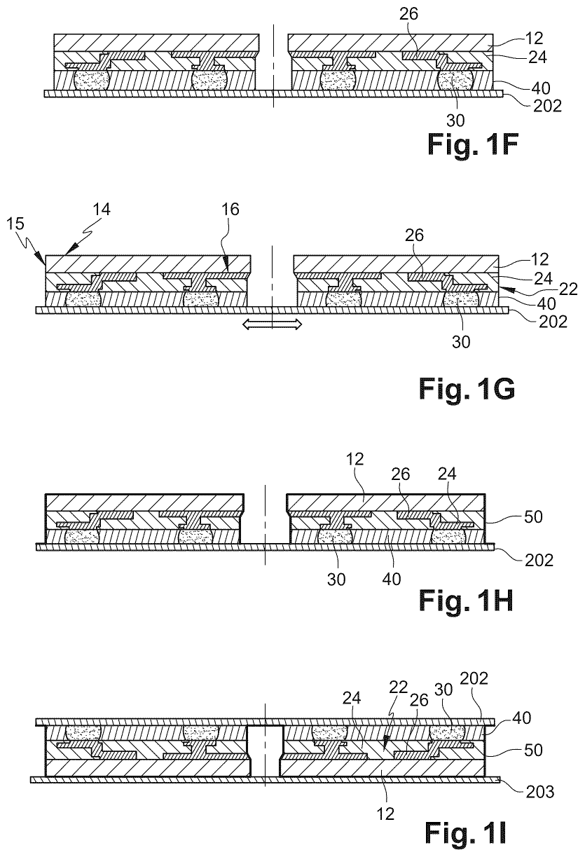

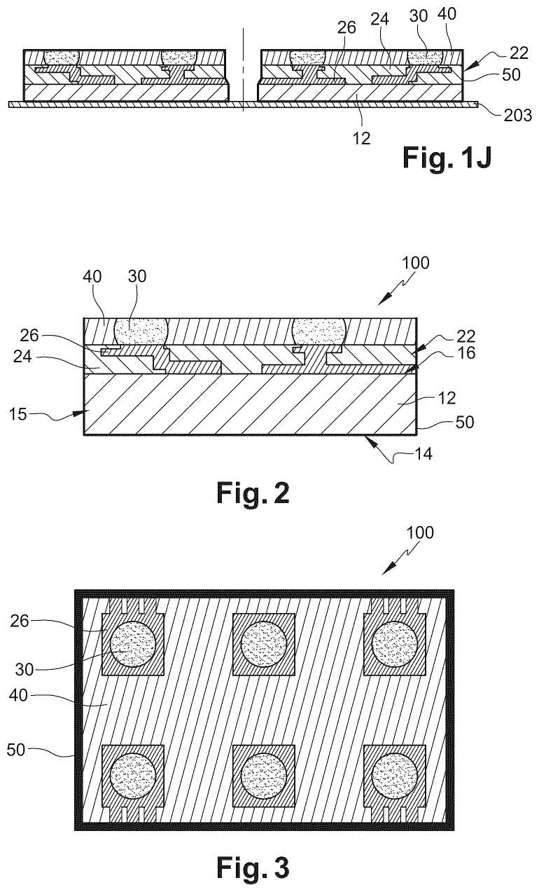

At the end of the method, a chip 100 comprising an electromagnetic coating 50 is obtained (FIG. 2 and FIG. 3).

Each of the different steps will now be described in further detail.

During step a), the active parts of the chips 100 are formed on a same substrate 12 and do not have been individualized yet.

During step a), one or a plurality of discrete components, not shown, may have already been formed. The one or a plurality of discrete components are, for example, selected from among transistors, diodes, thyristors, triacs, filters, etc. Chip 100 may comprise one or a plurality of electronic circuits. Chip 100 enables to implement different electronic functions.

The chips may be identical or different.

Each electronic chip 100 comprises:
an insulating substrate 12,
an interconnection structure 22 covering substrate 12,
connection pads 30 arranged on interconnection structure 20.

According to an embodiment, at this stage of the procedure, substrate 12 corresponds to a plate.

Substrate 12 is an insulating substrate (“high insulative substrate”). It has for example a resistivity higher than 1 kΩ.cm. It is, for example, a resistive silicon substrate (HRSI for “High-Resistivity Silicon”) or a glass substrate. Any other highly electrically insulating or electrically insulating substrate can be used.

Substrate 12 has, for example, a thickness in the range from 100 to 900 μm, preferably from 300 to 900 μm, for example a thickness of approximately 725 μm.

Substrate 12 comprises a first surface 16 (upper surface or front side or active surface) and a second surface 14 (lower surface or back side). The two surfaces 14 and 16 are parallel to each other. They are coupled together by side walls 15. An insulating layer may cover lower surface 14.

Interconnection structure 22 comprises one or a plurality of (two or three for example) conductive tracks 26 levels and insulating layers 24.

Conductive tracks 26 are, for example, made of one or a plurality of materials selected from among copper, a copper alloy, titanium, a titanium alloy, titanium nitride, gold, tungsten, platinum, and a platinum alloy. It may also be aluminum. According to an embodiment, the thickness of each metal track 26 is in the range from 2 to 40 μm, for example from 2 to 12 μm. Tracks having larger thicknesses favor the contact surface area between track 26 and electromagnetic coating 50. Tracks 26 of lower thicknesses will be easier to cut.

Insulating layer 24 may be a multilayer formed of a plurality of insulating layers. According to an embodiment, the thickness of each insulating layer 24 is in the range from 0.5 μm to 15 μm.

Insulating layer 24 may be made of a dielectric material, for example an oxide or a nitride, preferably, it is a silicon oxide (SiO₂), a silicon nitride (for example Si₃N₄). Alternatively, the insulating layer may be made of polymer, and particularly of polyimide.

Interconnection structure 22 comprises an upper surface, a lower surface, and sides. The lower surface is in contact with the upper surface 16 of substrate 12.

Metal tracks 26 are flush with the upper surface to form connection areas. The connection areas (also called electric contacts) enable to connect the electric terminals of the chip 100 to other elements (chips or printed circuits for example), by means of connection pads 30.

The electric connection areas are also called “UBM” (“Under Bump Metallization”). Preferably, there are at least two connection areas. For example, in FIG. 3, six electric connection areas are shown.

The electric connection areas are, for example, at a distance of from 10 to 30 μm from the side wall of the chip. This distance depends on the chip. It can be several hundred micrometers or even a millimeter depending on the component produced.

Part of the metal tracks 26 is accessible from the sides of interconnection areas 22 to be able to be directly connected to metal coating 50, to perform a grounding of coating 50. The metal tracks are accessible on at least one side of chip 100. They may be accessible on a plurality of sides of chip 100, for example on two opposite sides.

Connection pads 30 are bonded to the connection areas. Connection pads 30 are, advantageously, soldered to the electric connection areas. Connection pads 30 are formed of an electrically-conductive and wettable (that is, solderable or weldable) material, that is, a material on which it is possible to perform a soldering. For example, the metal pads are made of a solderable material based on tin, typically SnAgCu or Cu/SnAg.

During step b), a resin layer 40 is deposited on the front side on interconnection structure 22 and on connection pads 30.

Resin 40 is an electrically-insulating resin. It may be a thermosetting resin or a thermoplastic resin. The material will be selected not to be fusible over the range of temperatures of use of electronic components. The resin may be selected from the group comprising: epoxy-type resins, and phenolic-type resins, acrylic-type resins.

The resin may also comprise electrically-insulating particles. The particles are, for example, oxide particles, and in particular alumina or silica particles.

Resin layer 40 comprises an upper surface, a lower surface in contact with interconnection structure 22, and a lateral surface.

After having been deposited, resin 40 is thinned to leave access to the upper portion of the pads.

During step c), substrate 12 may be thinned on its back side 14 and/or a resin layer 30 may be deposited on the back of substrate 12. For this purpose, the structure is flipped and bonded by its front side to a first support 201. First support 201 is, for example, an adhesive strip band. The structure is then thinned on its back side so that substrate 12 has its final thickness.

Preferably, the lateral surfaces of substrate 12 are not covered with a resin.

During step d), substrate 110 is cut between chips 100 to singulate the chips. For this purpose, trenches, thoroughly crossing the structure obtained at step c), are formed. Trenches 120 define the lateral contours of chips 100.

The width of trenches 120 is, for example, in the range from 20 to 80 μm.

This cutting step may be performed by means of a cutting or etching device. The cutting device is, for example, a mechanical cutting tool, such as saw. The cutting may be performed with one blade or two blades.

It may also be a laser cutting (“laser grooving” or “laser dicing”) or plasma dicing. These different cutting processes can also be used jointly.

Trenches can also be formed by a laser dislocation cutting step (stealth dicing) followed by an expansion step. In the stealth dicing step, a specific laser is used to generate dislocations within the substrate, in the cutting paths. These dislocations are defects in the thickness of the substrate which, under the effect of mechanical stress, will enable the chips to be separated. Simply stretch the adhesive carrier to pull the chips apart and deposit the material.

It is also possible to implement a first step during which a laser is used to cut the upper portion of the device extending from the front side to the lower portion of interconnection structure 22, and then a second step during which a saw is used to cut substrate 12. The use of a laser to cut the tracks (particularly made of copper) and the insulating layer of the interconnection structure enables to obtain a clear cut and to avoid delamination phenomena.

The cutting step is, preferably, performed from the front side. For this purpose, the structure obtained at step c) is bonded by its back side to a first adhesive 201.

Once the substrate has been cut, the structure is flipped to be able to deposit the coating from the back side. For this purpose, a second adhesive 202 is bonded to the front side of the cut chips (step e)). Second adhesive 202 is a stretchable adhesive.

First adhesive 201 is removed (step f)). Then, second adhesive 202 is stretched to increase the distance between two chips 100 and leave more easily access to the sides of the electronic chips (step g)). This step is optional. It depends on the width of the cut made in step d) and/or the type of process used to deposit the shielding layer 50.

Alternatively, during step c), chips 100 may be bonded to a stretchable adhesive by their front side. The cutting step (step c) and the step of deposition of the coating (step h) may then be carried out on the same stretchable adhesive. There is no need to flip chips 100.

The various adhesives used in the process can be ultraviolet (UV) sensitive adhesives for cutting applications ('UV dicing tape').

Step ii) is then implemented.

The coating may be deposited at once. In other words, the back side and the lateral surface of chip 100 are simultaneously covered.

Preferably, coating 50 is deposited by liquid deposition. Electromagnetic coating 50 is deposited, for example, by spraying of a solution or by inkjet. It can also be screen-printed. The coating can also be deposited by evaporation or atomic layer deposition (ALD).

The solution or the ink used contains conductive nanoparticles, typically metallic nanoparticles, for example silver nanoparticles. Alternatively, nanoparticles can be particles or microparticles.

Depending on the process used, the flank 15 of the chip may be partially or completely covered by the coating. For example, the sidewall of the resin layer 40 may or may not be covered by the coating 50.

At the end of the method, a chip 100 such as shown in FIGS. 2 and 3 is obtained. Electronic chip 100 comprises:
an insulating substrate 12 comprising a lower surface 14, a lateral surface 15, and an upper surface 16,
an interconnection structure 22 covering the upper surface 16 of the substrate, interconnection structure 22 comprising an upper surface, sides, and a lower surface in contact with substrate 12, the interconnection structure comprising an insulating layer 24 having conductive tracks 26 formed therein, the conductive emerging on the one hand onto the upper surface of the interconnection structure to form connection areas and on the other hand onto one of the sides of interconnection structure 22,
connection pads 30 being connected to the connection areas,
a resin 40 covering the interconnection structure and leaving access to part of the connection pads,
a conductive coating 50 covering and being in contact with the lateral surface 15 and the lower surface 14 of the substrate of chip 100 as well as with the sides of interconnection structure 22, to connect conductive tracks 26 to the conductive coating on the side of interconnection structure 22.

The conductive coating is, for example, a metallic coating. It may be silver.

The conductive tracks 26 emerging onto the side of interconnection structure 22 may comprise a comb-shaped end (FIG. 3) or have a solid shape, for example a band shape.

A same chip 100 may comprise identical or different tracks. Conductive tracks 26 may be symmetrical or asymmetrical.

It will be desired to maximum the surface area of contact between metal tracks 26 and conductive coating 50 to ensure a good electric contact.

Preferably, the different conductive tracks 26 emerge onto a plurality of sides of interconnection structure 22. Preferably, conductive tracks 26 emerge onto two opposite sides of interconnection structure 22.

Tracks 26 are preferably made of copper or aluminum.

Each electronic chip 100 may then be bonded to an external element, for example another chip, a package, a printed circuit board, or another electronic chip.

Such electronic chips find applications in many industrial fields, and in particular, in the automotive field, for personal electronics, in particular for communication equipments, or in computers and peripherals.

These may, for example, be 5G connection devices or, more generally, connected devices.

They may also be advanced driver-assistance systems (ADAS).

The microchip can be used in a smartphone or for the Internet of Things (IoT). The device is connected, for example, via 5G, WIFI or Ultra-Wide Band (UWB).

The chip may also be of interest in other fields, such as industrial applications, particularly in green energy.

Such applications are given by way of illustration and are not limitative.

Various embodiments and variants have been described. Those skilled in the art will understand that certain features of these various embodiments and variants may be combined, and other variants will occur to those skilled in the art.

Various embodiments and variants have been described. Those skilled in the art will understand that certain features of these various embodiments and variants may be combined, and other variants will occur to those skilled in the art.

1. A method of manufacturing an electronic chip of CSP type having an electromagnetic shielding comprising:
i) providing an electronic chip of CSP type comprising:
an insulating substrate having a resistivity higher than 1 kΩ.cm and comprising a lower surface, a lateral surface, and an upper surface, the active parts of the electronic chip being formed on the substrate,
an interconnection structure covering the upper surface of the substrate, the interconnection structure comprising an insulating layer having conductive tracks formed therein, connection pads being arranged on the interconnection structure, the conductive tracks being arranged so as to emerge onto at least one of one or more sides of the interconnection structure,
a resin covering an upper surface of the interconnection structure and partially coating the connection pads to be able to connect them to an external element; and
ii) forming a conductive coating on the lateral surface and on the lower surface of the substrate as well as on the sides of the interconnection structure, the conductive coating covering and being in contact with the lateral surface and the lower surface of the substrate of the electronic chip as well as with the sides of the interconnection structure, whereby the conductive coating is connected to the conductive tracks on at least one of the sides of the interconnection structure.

2. The method of claim 1, wherein step ii) is carried out by spraying of a solution or by inkjet.

3. The method of claim 2, wherein the solution or an ink contains silver nanoparticles.

4. The method of claim 1, wherein the electronic chip provided at step i) is obtained according to the following steps:
providing a substrate covered by the interconnection structure, the connection pads being arranged on the interconnection structure, the conductive tracks being arranged so as to emerge onto at least one of the sides of the interconnection structure,
depositing the resin on the interconnection structures and on the connection pads,
thinning the resin to leave access to part of the connection pads, and
cutting the substrate into different electronic chips.

5. The method of claim 1, wherein the electronic chip provided at step i) is obtained according to the following steps:
providing a substrate covered by the interconnection structure, the connection pads being arranged on the interconnection structure, the conductive tracks being arranged so as to emerge onto at least one of the sides of the interconnection structure,
depositing the resin on the interconnection structures and on the connection pads,
thinning the resin to leave access to part of the connection pads,
thinning the substrate or covering the lower surface of the electronic chip being formed on the substrate of the electronic chip with an additional resin layer, and
cutting the substrate into different electronic chips.

6. An electronic chip of CSP type having an electromagnetic shielding comprising:
an insulating substrate having a resistivity higher than 1 kΩ.cm and comprising a lower surface, a lateral surface, and an upper surface, the active parts of the electronic chip being formed on the substrate,
an interconnection structure covering the upper surface of the substrate, the interconnection structure comprising an insulating layer having conductive tracks formed therein, connection pads being arranged on the interconnection structure, the conductive tracks being arranged so as to emerge onto at least one of one or more sides of the interconnection structure,
a resin covering the interconnection structure and leaving access to part of the connection pads, and
a conductive coating covering and being in contact with the lateral surface and the lower surface of the substrate of the chip as well as with the sides of the interconnection structure, so as to connect the conductive tracks to the conductive coating on at least one of the sides of the interconnection structure.

7. The electronic chip of claim 6, wherein a thickness of the conductive tracks is in a range from 2 to 12 μm.

8. The electronic chip of claim 6, wherein a width of the conductive tracks is greater than 10 μm.

9. The electronic chip of claim 6, wherein the conductive coating is made of silver.

10. The electronic chip of claim 6, wherein the conductive tracks, emerging onto the side of the interconnection structure, comprise a comb-shaped end.

11. The electronic chip of claim 6, wherein the conductive tracks emerge onto two opposite sides of the interconnection structure.
